(19) United States
(12) Patent Application Publication
(10) Pub. No.: US 2025/0107210 A1
(43) Pub. Date: Mar. 27, 2025

(54) SEMICONDUCTOR DEVICE AND METHOD FOR MANUFACTURING SAME

(71) Applicants: Kabushiki Kaisha Toshiba, Tokyo (JP); Toshiba Electronic Devices & Storage Corporation, Tokyo (JP)

(72) Inventor: Kanako KOMATSU, Yokohama Kanagawa (JP)

(21) Appl. No.: 18/442,336

(22) Filed: Feb. 15, 2024

(30) Foreign Application Priority Data
Sep. 22, 2023 (JP) 2023-158395

(51) Int. Cl. H01L 29/49; H01L 21/285; H01L 21/762

(52) U.S. Cl. CPC H10D 64/668; H01L 21/28518; H01L 21/76205

(57) ABSTRACT

A semiconductor device includes a semiconductor substrate, an insulating film located on the semiconductor substrate, a silicon film located on the insulating film, a silicide layer located on the silicon film, and a first contact and a second contact connected to portions of the silicide layer. A first recess is formed in an upper surface of the insulating film. The silicon film includes an impurity. A second recess is formed in an upper surface of the silicon film in a region directly above the first recess. The silicide layer contacts the silicon film. A region directly above the second recess is interposed between the portions.

### CROSS-REFERENCE TO RELATED APPLICATIONS

This application is based upon and claims the benefit of priority from Japanese Patent Application No.2023-158395, filed on Sep. 22, 2023; the entire contents of which are incorporated herein by reference.

### FIELD

Embodiments described herein relate generally to a semiconductor device and a method for manufacturing a semiconductor device.

### BACKGROUND

A fuse may be provided to configure OTPROM (One Time Programmable Read Only Memory) or the like in a semiconductor device. Fuses include a type that is cut by irradiating a laser, and a type that is cut by causing a current to flow. The type that is cut by causing a current to flow has the advantage of being able to be located in a lower portion of a stacked structure, but requires a relatively large current supply circuit for the cutting.

### BRIEF DESCRIPTION OF THE DRAWINGS

FIG. 1 is a plan view showing a semiconductor device according to a first embodiment;

FIG. 2 is a cross-sectional view along line A-A′ shown in FIG. 1;

FIGS. 3A to 3D are process cross-sectional views showing a method for manufacturing the semiconductor device according to the first embodiment;

FIGS. 4A to 4C are cross-sectional views showing an operation of the semiconductor device according to the first embodiment;

FIG. 5 is a plan view showing a semiconductor device according to a comparative example;

FIG. 6 is a cross-sectional view along line B-B′ shown in FIG. 5;

FIG. 7 is a cross-sectional view showing a semiconductor device according to a first modification of the first embodiment;

FIG. 8 is a cross-sectional view showing a semiconductor device according to a second modification of the first embodiment;

FIG. 9 is a cross-sectional view showing a semiconductor device according to second embodiment;

FIG. 10 is a plan view showing a semiconductor device according to a third embodiment;

FIG. 11 is a cross-sectional view along line C-C′ shown in FIG. 10;

FIGS. 12A to 12C are process cross-sectional views showing a method for manufacturing the semiconductor device according to the third embodiment;

FIG. 13 is a plan view showing a semiconductor device according to a fourth embodiment;

FIG. 14 is a cross-sectional view along line D-D′ shown in FIG. 13;

FIG. 15 is a cross-sectional view along line E-E′ shown in FIG. 13;

FIGS. 16A to 16D are process cross-sectional views showing a method for manufacturing the semiconductor device according to the fourth embodiment;

FIG. 17 is a plan view showing a semiconductor device according to a first modification of the fourth embodiment;

FIG. 18 is a cross-sectional view along line F-F′ shown in FIG. 17;

FIG. 19 is a cross-sectional view along line G-G′ shown in FIG. 17;

FIG. 20 is a cross-sectional view showing a semiconductor device according to a second modification of the fourth embodiment;

FIG. 21 is a cross-sectional view showing a semiconductor device according to a third modification of the fourth embodiment;

FIG. 22 is a process cross-sectional view showing a method for manufacturing the semiconductor device according to the third modification of the fourth embodiment;

FIG. 23 is a plan view showing a semiconductor device according to a fifth embodiment;

FIG. 24 is a cross-sectional view along line H-H′ shown in FIG. 23;

FIG. 25 is a cross-sectional view along line I-I′ shown in FIG. 23;

FIGS. 26A to 26C are process cross-sectional views showing a method for manufacturing the semiconductor device according to the fifth embodiment;

FIG. 27 is a plan view showing a semiconductor device according to a modification of the fifth embodiment;

FIG. 28 is a cross-sectional view along line J-J′ shown in FIG. 27;

FIG. 29 is a cross-sectional view along line K-K′ shown in FIG. 27; and

FIGS. 30A to 31B are plan views showing other embodiments.

### DETAILED DESCRIPTION

In general, according to one embodiment, a semiconductor device includes a semiconductor substrate, an insulating film located on the semiconductor substrate, a silicon film located on the insulating film, a silicide layer located on the silicon film, and a first contact and a second contact connected to portions of the silicide layer. A first recess is formed in an upper surface of the insulating film. The silicon film includes an impurity. A second recess is formed in an upper surface of the silicon film in a region directly above the first recess. The silicide layer contacts the silicon film. A region directly above the second recess is interposed between the portions.

In general, according to one embodiment, a method for manufacturing a semiconductor device includes forming a first LOCOS film and a second LOCOS film at an upper surface of a semiconductor substrate so that the first LOCOS film and the second LOCOS film are connected to each other. The method includes forming a silicon film on a region including a connection portion between the first LOCOS film and the second LOCOS film. The silicon film includes an impurity. The method includes forming a silicide layer at an upper surface of the silicon film. The method includes connecting a first contact and a second contact to regions of the silicide layer. A region directly above the connection portion is interposed between the regions of the silicide layer.

### First Embodiment

The semiconductor device 1 according to the embodiment is a semiconductor device that includes a fuse. For example, the fuse is included in an OTPROM.

### Configuration

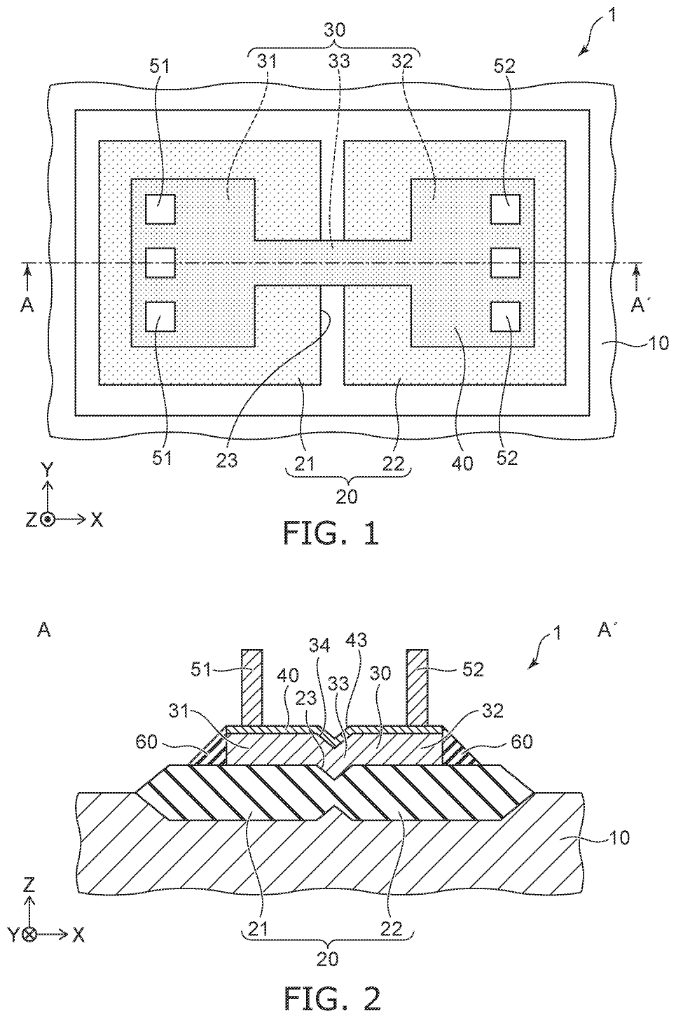

FIG. 1 is a plan view showing a semiconductor device according to the embodiment.

FIG. 2 is a cross-sectional view along line A-A′ shown in FIG. 1.

As shown in FIGS. 1 and 2, the semiconductor device 1 according to the embodiment includes a semiconductor substrate 10, an insulating film 20, a silicon film 30, a silicide layer 40, contacts 51 and 52, and a sidewall 60. The sidewall 60 is not illustrated in FIG. 1. This is similar for other plan views described below as well.

The semiconductor substrate 10 is made of, for example, single-crystal silicon (Si); and the conductivity type of each portion is set to the n-type or the p-type by introducing an impurity to the portion. The insulating film 20 is located on the semiconductor substrate 10 and is made of an insulating material, e.g., silicon oxide (SiO₂).

According to the embodiment, the insulating film 20 includes two LOCOS (local oxidation of silicon) films 21 and 22. The LOCOS films 21 and 22 are formed by thermal oxidation of the upper layer portion of the semiconductor substrate 10. The peripheral portions of the LOCOS films 21 and 22 each have bird beak shapes and become thin toward the edges. An end portion of the LOCOS film 21 and an end portion of the LOCOS film 22 are connected to each other. Therefore, a recess 23 is formed in the upper surface of the boundary portion between the LOCOS film 21 and the LOCOS film 22.

The silicon film 30 is made of polysilicon into which an impurity is introduced. Although not particularly limited, the impurity that is introduced to the silicon film 30 is, for example, boron (B) or arsenic (As). The silicon film 30 includes pad portions 31 and 32, and a fuse portion 33 located between the pad portion 31 and the pad portion 32. In the example shown in FIG. 1, the width of the fuse portion 33 is less than the width of the pad portion 31 and the width of the pad portion 32. However, the width of the fuse portion 33 may be equal to or greater than the width of the pad portion 31 and the width of the pad portion 32. The pad portions 31 and 32 and the fuse portion 33 are formed to have a continuous body.

The fuse portion 33 of the silicon film 30 is located at a position straddling the recess 23 of the insulating film 20. The pad portion 31 and the pad portion 32 are located at two sides of the recess 23 when viewed from above. A recess 34 is formed in the region of the upper surface of the fuse portion 33 directly above the recess 23.

The silicide layer 40 is made of a compound of silicon and a metal, and is made of, for example, nickel silicide (NiSi) or cobalt silicide (CoSi). The silicide layer 40 is formed of the silicided upper layer portion of the silicon film 30 and is continuously formed with the silicon film 30. A recess 43 that reflects the shape of the recess 23 is formed in the region of the silicide layer 40 directly above the recess 23.

The contacts 51 and 52 are located on the silicide layer 40. The contact 51 is connected to a portion of the silicide layer 40 located on the pad portion 31 of the silicon film 30; and the contact 52 is connected to a portion of the silicide layer 40 located on the pad portion 32 of the silicon film 30. Accordingly, the contacts 51 and 52 are connected to portions of the silicide layer 40 that are separated from each other so that the recess 43 is interposed between the portions. In the specification, “connected” refers to an electrical connection.

The sidewall 60 is insulative and is, for example, a stacked film including a silicon oxide layer and a silicon nitride layer. The sidewall 60 is located on the side surface of the silicon film 30.

An XYZ orthogonal coordinate system is employed for convenience of description in the specification hereinbelow. A direction orthogonal to the upper surface of the semiconductor substrate 10 is taken as a “Z-direction”; the direction from the contact 51 toward the contact 52 is taken as an “X-direction”; and a direction orthogonal to the Z-direction and X-direction is taken as a “Y-direction”. The longitudinal direction of the fuse portion 33 is the X-direction; and the width direction of the fuse portion 33 is the Y-direction. The number of the contacts 51 and the number of the contacts 52 are arbitrary. When multiple contacts 51 and multiple contacts 52 are provided, the contacts 51 and 52 are arranged along, for example, the Y-direction. Although a direction that is in the Z-direction from the semiconductor substrate 10 toward the silicide layer 40 also is called “up/above/higher than”, and the opposite direction also is called “down/below/lower than”, these expressions are for convenience and are independent of the direction of gravity. In the specification, “region directly above” refers to a region that is on an object and overlaps the object when viewed along the Z-direction. In other words, a region directly above an object has the same position as the object in the X-direction and Y-direction. Similarly, “region directly under” refers to a region that is under an object and overlaps the object when viewed along the Z-direction.

### Manufacturing Method

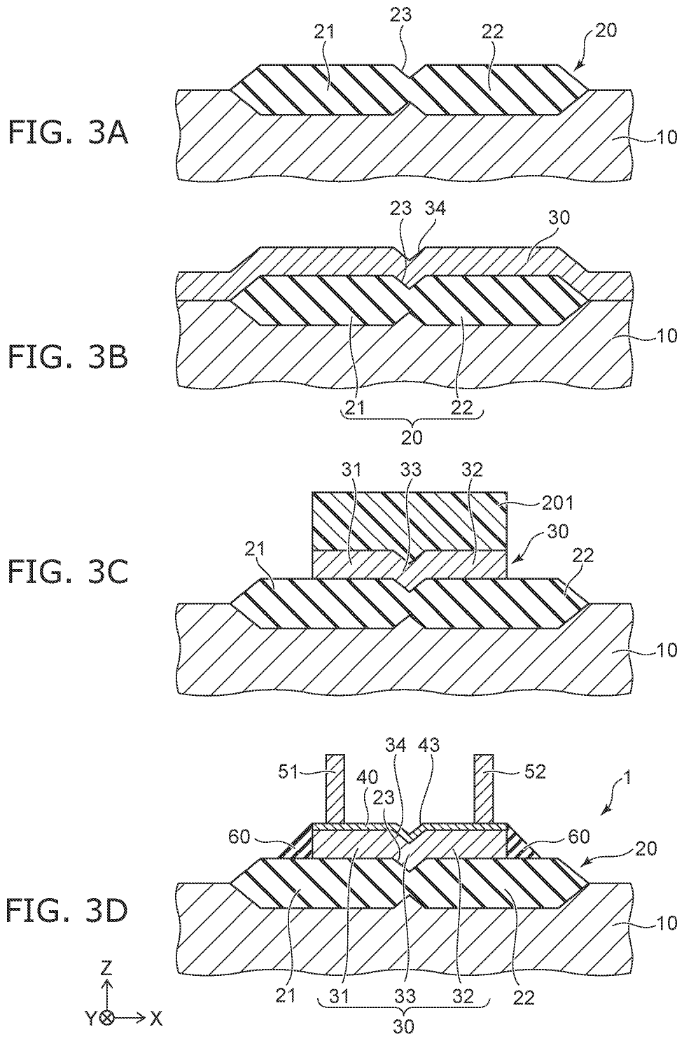

FIGS. 3A to 3D are process cross-sectional views showing a method for manufacturing the semiconductor device according to the embodiment.

First, as shown in FIG. 3A, the LOCOS film 21 and the LOCOS film 22 are formed by selectively performing thermal oxidation treatment of the upper layer portion of the semiconductor substrate 10. A recess 23 is formed in the upper surface of the boundary portion of the LOCOS film 21 and the LOCOS film 22 due to their bird beak shapes. The insulating film 20 includes the LOCOS film 21 and the LOCOS film 22.

Then, as shown in FIG. 3B, the silicon film 30 is formed by depositing silicon and an impurity by, for example, CVD (Chemical Vapor Deposition). The silicon film 30 is formed of polysilicon including an impurity. The recess 34 is formed in the region of the upper surface of the silicon film 30 directly above the recess 23.

Continuing as shown in FIG. 3C, a resist mask 201 is formed in a region including the region directly above the recess 23. Then, the silicon film 30 is etched using the resist mask 201 as a mask. As a result, the silicon film 30 is patterned, and the pad portions 31 and 32 and the fuse portion 33 are formed to have a continuous body. The recess 34 is located at the upper surface of the fuse portion 33. Subsequently, the resist mask 201 is removed.

Then, as shown in FIG. 3D, the insulating sidewall 60 is formed on the side surface of the silicon film 30 by forming a silicon oxide layer and a silicon nitride layer and by performing anisotropic etching such as RIE, etc. Then, the silicide layer 40 is formed on the upper surface of the silicon film 30 by depositing a metal on the silicon film 30 and performing heat treatment. The recess 43 is formed in the region of the silicide layer 40 directly above the recess 23.

Continuing, an inter-layer insulating film (not illustrated) is formed on the semiconductor substrate 10 to cover the insulating film 20, the silicon film 30, the silicide layer 40, and the sidewall 60. Then, contact holes are formed in the inter-layer insulating film to reach the silicide layer 40. Then, the contacts 51 and 52 are formed in the contact holes. Thus, the semiconductor device 1 is manufactured.

### Operation

An operation of cutting the fuse portion 33 of the silicon film 30 will now be described.

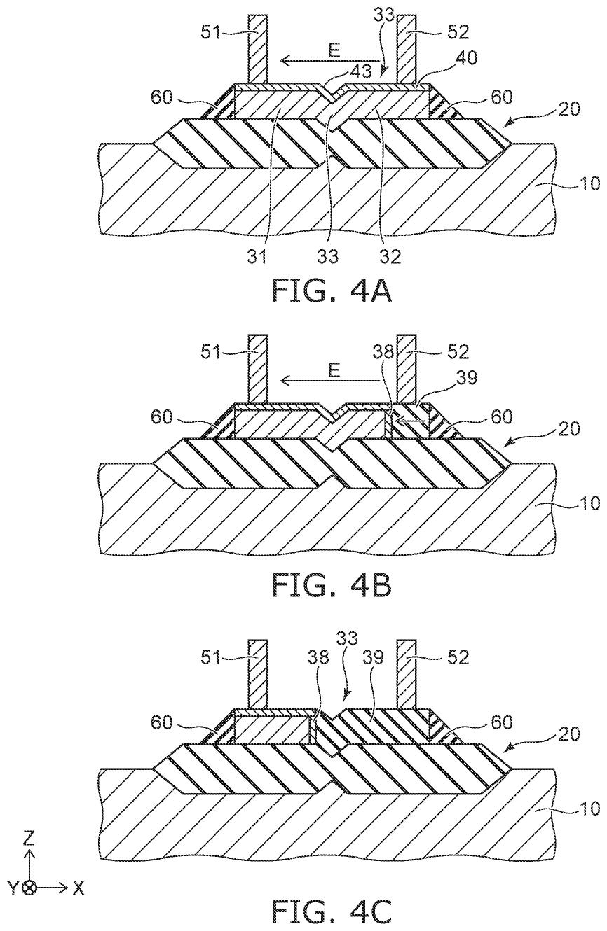

FIGS. 4A to 4C are cross-sectional views showing an operation of the semiconductor device according to the embodiment.

As shown in FIG. 4A, the contact 51 is used as a positive electrode and the contact 52 is used as a negative electrode to apply a voltage to the fuse portion 33 to be cut. As a result, an electron current E flows from the contact 52 toward the contact 51. The electron current E flows mainly through the silicide layer 40, which generates Joule heat. At this time, a large amount of heat is generated at the recess 43 vicinity of the silicide layer 40 because the current concentrates at the recess 43.

As shown in FIG. 4B, electromigration occurs due to the heat generated by the electron current E and the movement of electrons; and metal atoms inside the silicide layer 40 move toward the contact 51. The electron current E also flows through the silicon film 30. At this time, the electron current E concentrates at the recess 34. As a result, a large amount of heat is generated also at the recess 34 vicinity. Therefore, impurity atoms inside the silicon film 30 also move toward the contact 51 by electromigration.

As a result, a high-resistance portion 39 that has reduced metal and impurity concentrations is formed in the regions of the silicide layer 40 and the silicon film 30 at the contact 52 side. As the electron current E flows, the high-resistance portion 39 spreads toward the contact 51. A high-concentration portion 38 that has a higher impurity concentration is formed between the high-resistance portion 39 and the silicon film 30.

As shown in FIG. 4C, when the high-resistance portion 39 makes up a certain portion of the fuse portion 33 and the electrical resistance of the entire fuse portion 33 increases, the contact 51 and the contact 52 become substantially insulated. Thus, the fuse portion 33 is electrically disconnected. In the specification hereinbelow, the fuse portion being electrically disconnected by the high-resistance portion formed in the fuse portion is called simply “the fuse portion being cut”. Data is stored in the OTPROM by selectively cutting multiple fuse portions 33.

### Effects

According to the embodiment, by forming the recess 23 in the insulating film 20, the recess 34 is formed in the silicon film 30, and the recess 43 is formed in the silicide layer 40. Therefore, the electron current E concentrates and generates heat at the recess 43 vicinity when the electron current E is caused to flow between the contact 51 and the contact 52. The electron current E also concentrates and generates heat at the recess 34 vicinity of the silicon film 30. As a result, electromigration can be promoted, and the high-resistance portion 39 can be efficiently formed. As a result, the fuse portion 33 can be cut by a small current. When the electron current E for cutting the fuse portion 33 can be reduced, the circuit for supplying the electron current E can be smaller, and the semiconductor device 1 can have higher integration and a lower cost.

### Comparative Example

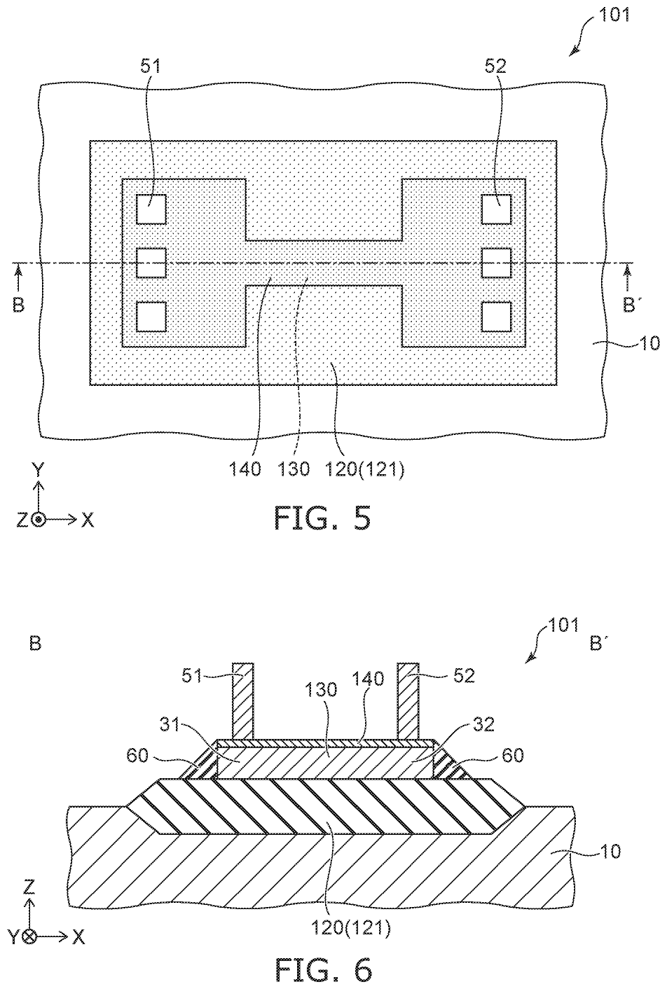

FIG. 5 is a plan view showing a semiconductor device according to a comparative example.

FIG. 6 is a cross-sectional view along line B-B′ shown in FIG. 5.

In the semiconductor device 101 according to the comparative example as shown in FIGS. 5 and 6, an insulating film 120 includes one LOCOS film 121; and a recess is not formed. Therefore, recesses are not formed in a silicon film 130 and a silicide layer 140.

In the semiconductor device 101 according to the comparative example as well, the fuse portion can be cut by the operation shown in FIGS. 4A to 4C. However, portions of concentrated current are not formed in the silicide layer 140 and the silicon film 130, and so heat is not generated efficiently, and electromigration is not promoted sufficiently. It is therefore necessary to cause a large current to flow to cut the fuse portion. As a result, a large current supply circuit is necessary, and higher integration and a lower cost of the semiconductor device 101 are obstructed.

### First Modification of First Embodiment

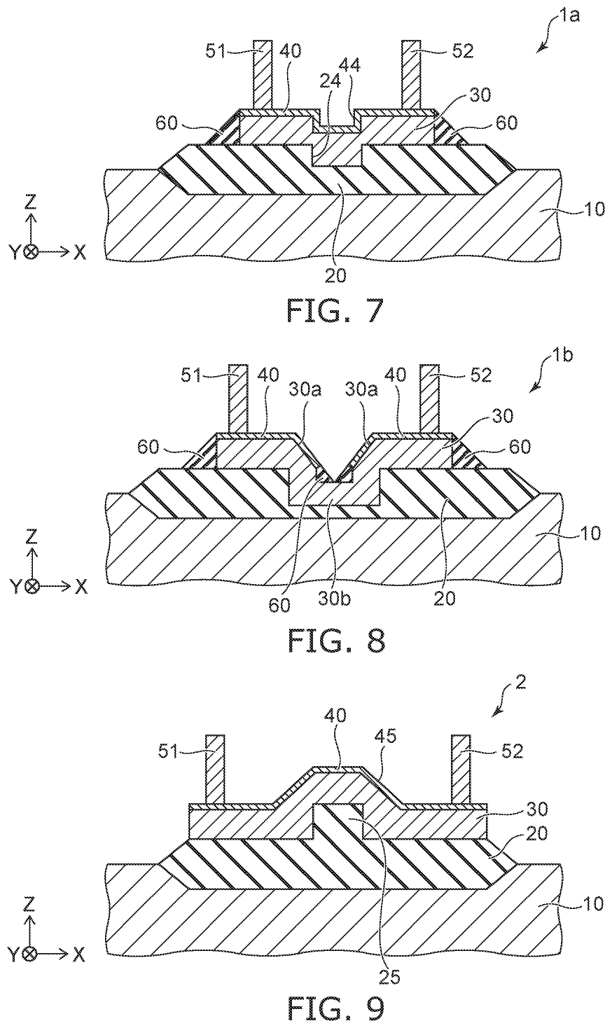

FIG. 7 is a cross-sectional view showing a semiconductor device according to the modification.

In the semiconductor device 1a according to the modification as shown in FIG. 7, a recess 24 is formed by selectively etching the insulating film 20. Then, the silicon film 30 is formed to straddle the recess 24; and the silicide layer 40 is formed. As a result, a recess 44 is formed in the region of the silicide layer 40 directly above the recess 24.

According to the modification as well, the fuse portion can be efficiently cut because the electron current E concentrates at the recess 44 of the silicide layer 40. Otherwise, the configuration, manufacturing method, operations, and effects of the modification are similar to those of the first embodiment.

### Second Modification of First Embodiment

FIG. 8 is a cross-sectional view showing a semiconductor device according to the modification.

When forming the silicon film 30 in the semiconductor device 1b according to the modification as shown in FIG. 8, for example, silicon is deposited and then the deposited silicon film is etched inside the chamber of a CVD film formation apparatus. The sidewall 60 remains at the region of the silicon film 30 directly above the recess 24. Subsequently, the silicide layer 40 is formed by siliciding.

As a result, in the semiconductor device 1b, a tilted portion 30a is formed in the region of the silicon film 30 directly above the side surface of the recess 24. A portion 30b at which the silicide layer 40 is not formed in the upper surface occurs at a portion of the region directly above the recess 24.

As a result, the electron current E flows through the portion 30b of the silicon film 30. The electrical resistance of the silicon film 30 is greater than the electrical resistance of the silicide layer 40, and so heat is generated effectively at the portion 30b. The electron current E also concentrates because the tilted portion 30a is thinner than the other portions of the silicon film 30. This concentration also allows the electron current E to effectively generate heat. Otherwise, the configuration, manufacturing method, operations, and effects according to the modification are similar to those of the first embodiment.

### Second Embodiment

The embodiment differs from the first embodiment in that a protrusion is formed instead of a recess in the insulating film 20.

FIG. 9 is a cross-sectional view showing the semiconductor device according to the embodiment.

In the semiconductor device 2 according to the embodiment as shown in FIG. 9, a protrusion 25 is located at the upper surface of the insulating film 20. The fuse portion 33 of the silicon film 30 is formed to straddle the protrusion 25. As a result, a protrusion 45 is formed in the region of the silicide layer 40 directly above the protrusion 25.

In the semiconductor device 2, the current concentrates and generates heat at the protrusion 45 of the silicide layer 40. Also, the current concentrates and generates heat at the portion of the silicon film 30 straddling the protrusion 25. As a result, electromigration can occur effectively, and the fuse can be cut by a small current. Otherwise, the configuration, manufacturing method, operations, and effects according to the embodiment are similar to those of the first embodiment.

### Third Embodiment

The embodiment differs from the first embodiment in that an opening is provided instead of a recess in the insulating film 20.

### Configuration

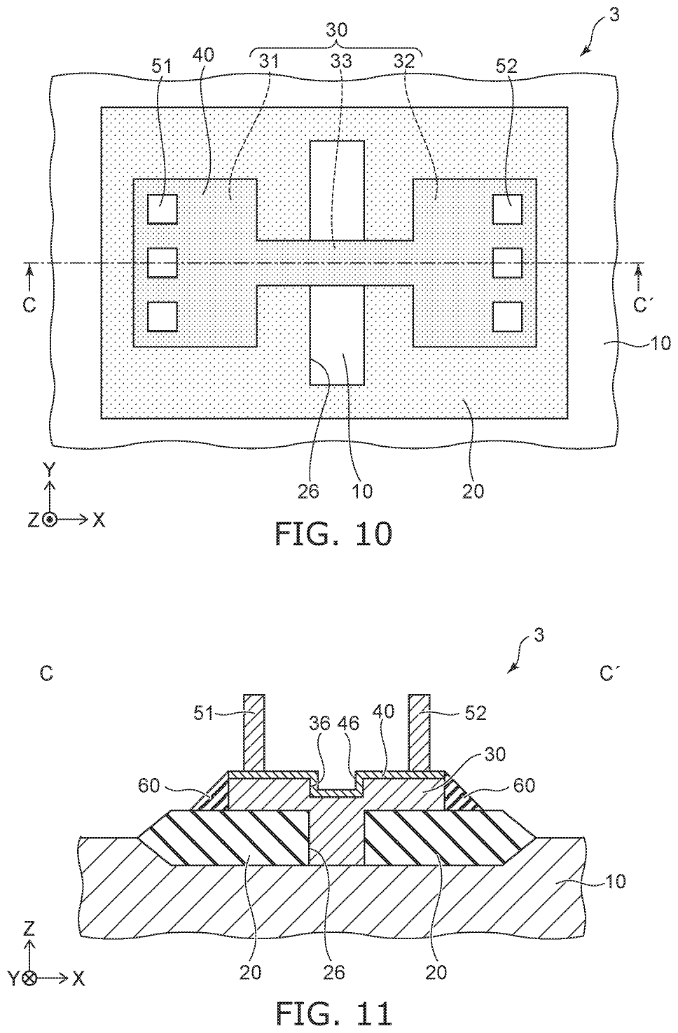

FIG. 10 is a plan view showing a semiconductor device according to the embodiment.

FIG. 11 is a cross-sectional view along line C-C′ shown in FIG. 10.

In the semiconductor device 3 according to the embodiment as shown in FIGS. 10 and 11, a groove-shaped opening 26 that extends in the Y-direction is formed in the insulating film 20. Then, the pad portions 31 and 32 of the silicon film 30 are located at positions on the insulating film 20 so that the opening 26 is interposed between the pad portion 31 and the pad portion 32; and the fuse portion 33 is arranged to straddle the opening 26. As a result, a recess 36 is formed in the region of the fuse portion 33 directly above the opening 26; and a recess 46 is formed in the region of the silicide layer 40 directly above the recess 36.

The resistivities of the silicide layer 40 and the silicon film 30 are much less than the resistivity of the semiconductor substrate 10, and so the electron current E that flows between the contact 52 and the contact 51 when cutting the fuse portion 33 substantially does not flow through the semiconductor substrate 10. Also, the silicon film 30 may be electrically isolated from the semiconductor substrate 10 by forming a p-n junction in the portion of the semiconductor substrate 10 contacting the silicon film 30.

### Manufacturing Method

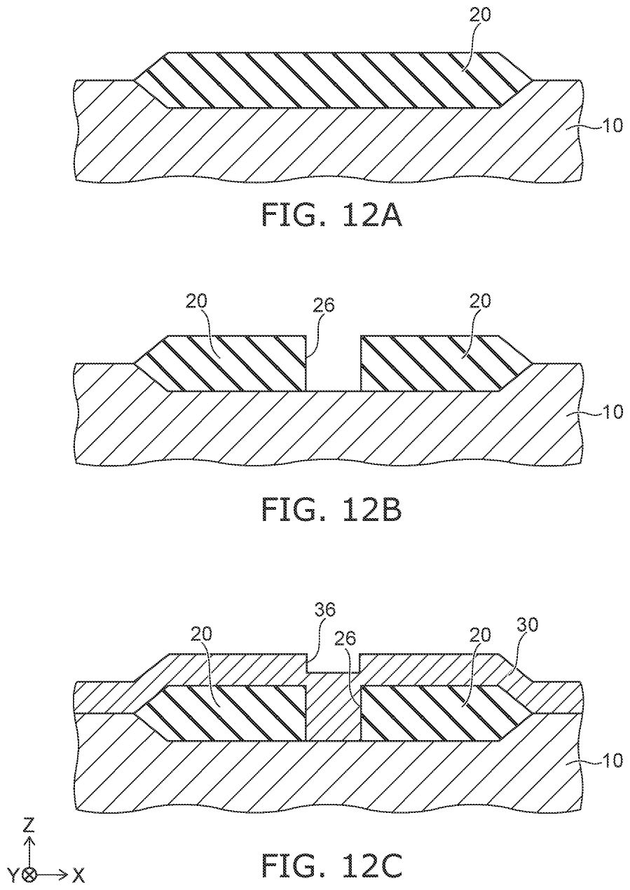

FIGS. 12A to 12C are process cross-sectional views showing a method for manufacturing the semiconductor device according to the embodiment.

First, as shown in FIG. 12A, the insulating film 20 is formed at the upper surface of the semiconductor substrate 10. For example, the insulating film 20 is formed of one LOCOS film.

Then, as shown in FIG. 12B, the opening 26 is formed by selectively etching the insulating film 20.

Continuing as shown in FIG. 12C, the silicon film 30 is formed by depositing silicon and an impurity on the entire surface. At this time, the recess 36 is formed in the region of the silicon film 30 directly above the opening 26.

The subsequent processes are similar to the processes shown in FIGS. 3C and 3D. Thus, the semiconductor device 3 is manufactured.

### Effects

In the semiconductor device 3, the electron current E concentrates and generates heat at the recess 46 vicinity of the silicide layer 40, and concentrates and generates heat at the recess 36 vicinity of the silicon film 30. As a result, electromigration can be promoted, and the fuse portion 33 can be cut by a small current. Otherwise, the configuration, manufacturing method, operations, and effects according to the embodiment are similar to those of the first embodiment.

### Fourth Embodiment

The embodiment differs from the third embodiment in that the opening 26 of the insulating film 20 is formed inside the silicon film 30 when viewed from above.

### Configuration

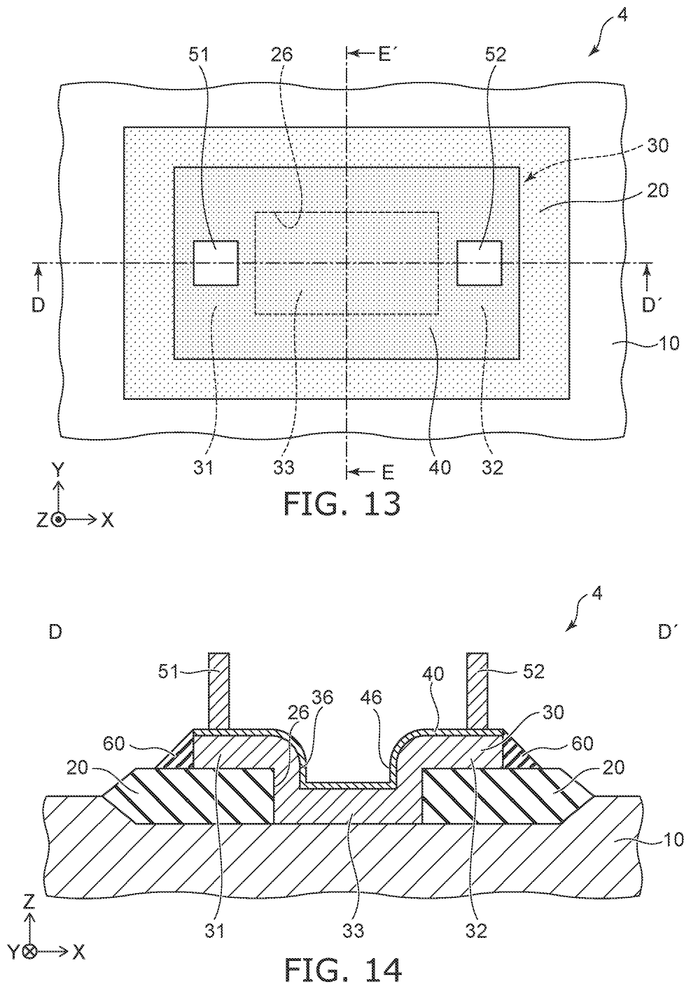

FIG. 13 is a plan view showing a semiconductor device according to the embodiment.

FIG. 14 is a cross-sectional view along line D-D′ shown in FIG. 13.

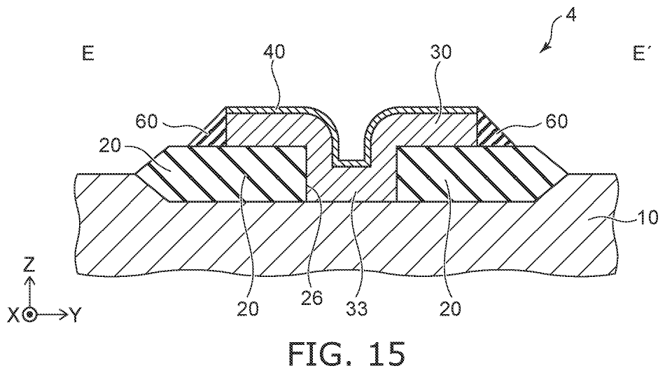

FIG. 15 is a cross-sectional view along line E-E′ shown in FIG. 13.

In the semiconductor device 4 according to the embodiment as shown in FIGS. 13 to 15, the opening 26 is rectangular when viewed from above; and the silicon film 30 is arranged to cover the entire opening 26. The pad portions 31 and 32 of the silicon film 30 are located at positions on the insulating film 20 so that the region directly above the opening 26 is interposed between the pad portions 31 and 32. The portion of the silicon film 30 located in the opening 26 and in the region directly above the opening 26 is used as the fuse portion 33.

When the silicon film 30 is thinner than the insulating film 20, the upper surface of the fuse portion 33 is positioned lower than the lower surfaces of the pad portions 31 and 32. The recess 36 of the silicon film 30 and the recess 46 of the silicide layer 40 are located inside the opening 26 when viewed from above. Although one contact 51 and one contact 52 are included in the semiconductor device 4, the numbers of the contacts 51 and 52 are arbitrary.

### Manufacturing Method

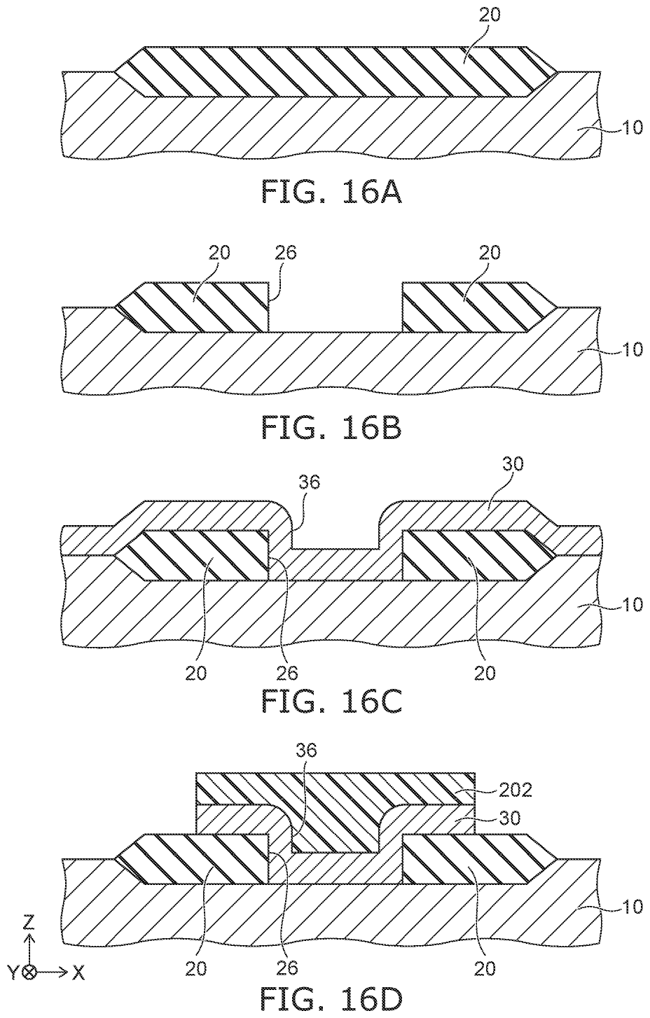

FIGS. 16A to 16D are process cross-sectional views showing a method for manufacturing the semiconductor device according to the embodiment.

First, as shown in FIG. 16A, the insulating film 20 is formed at the upper surface of the semiconductor substrate 10. The insulating film 20 is, for example, a LOCOS film.

Then, as shown in FIG. 16B, the opening 26 is formed in the insulating film 20.

Continuing as shown in FIG. 16C, the silicon film 30 is formed on the entire surface. The silicon film 30 also is formed inside the opening 26. The recess 36 of the silicon film 30 is formed inside the opening 26 when viewed from above.

Then, as shown in FIG. 16D, a resist mask 202 is formed on the silicon film 30. The resist mask 202 is formed to cover the entire opening 26. Then, the silicon film 30 is etched using the resist mask 202 as a mask.

Thereafter, the processes are similar to the processes shown in FIGS. 3C and 3D. Thus, the semiconductor device 4 is manufactured.

### Effects

In the semiconductor device 4 as well, the electron current E concentrates and generates heat at portions of the silicide layer 40 and the silicon film 30 that are not flat. Specifically, the electron current E concentrates and generates heat at the recess 46 of the silicide layer 40 and the recess 36 of the silicon film 30. The electron current E also concentrates because the film thickness of the silicon film 30 is nonuniform in the Y-direction. The fuse portion 33 can be effectively cut thereby. Otherwise, the configuration, manufacturing method, operations, and effects according to the embodiment are similar to those of the first embodiment.

### First Modification of Fourth Embodiment

The modification differs from the fourth embodiment in that two fuse portions 33 are formed in one opening 26 of the insulating film 20.

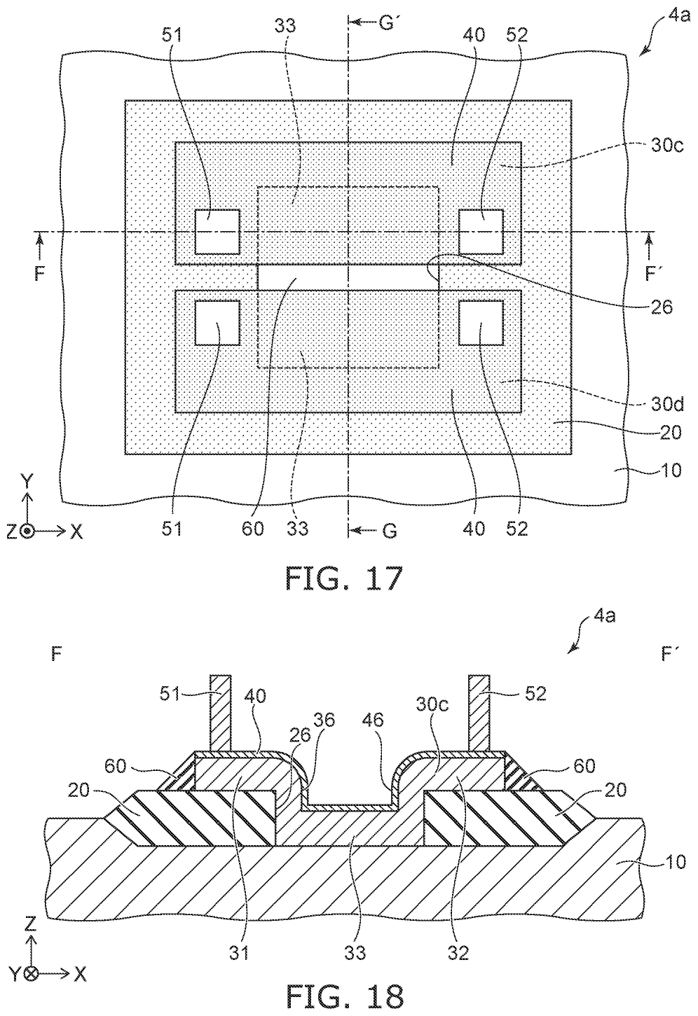

FIG. 17 is a plan view showing a semiconductor device according to the modification.

FIG. 18 is a cross-sectional view along line F-F′ shown in FIG. 17.

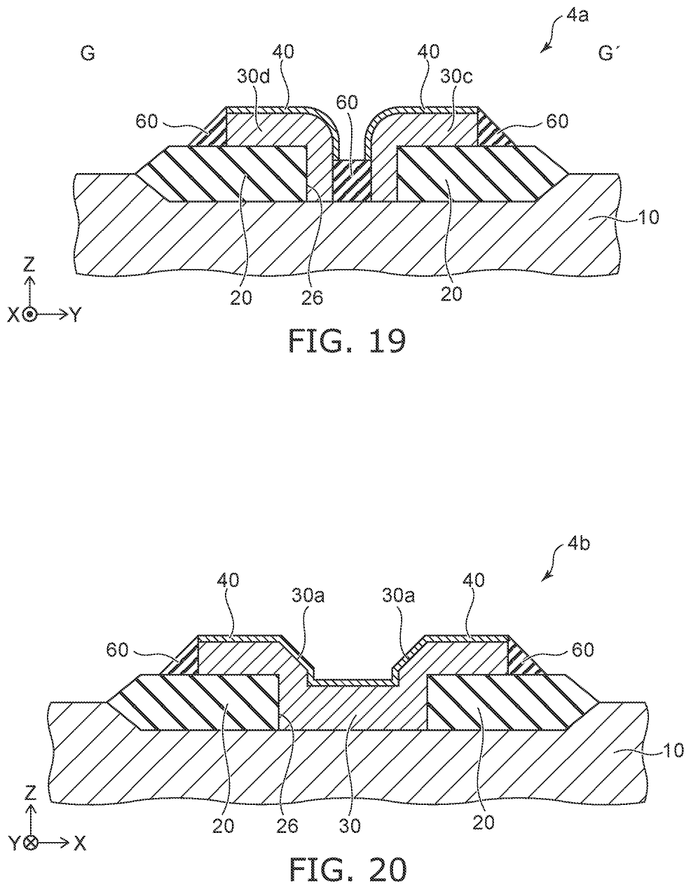

FIG. 19 is a cross-sectional view along line G-G′ shown in FIG. 17.

In the semiconductor device 4a according to the modification as shown in FIGS. 17 to 19, the width, i.e., the Y-direction length, of the opening 26 is greater than the width of the opening 26 of the semiconductor device 4. Two silicon films 30c and 30d are arranged to straddle one opening 26. The fuse portions 33 are formed respectively in the silicon films 30c and 30d.

According to the modification as well, similarly to the first embodiment, the electron current E concentrates in portions of the silicide layer and the silicon film that are not flat, so that electromigration can be promoted, and the fuse portion 33 can be cut by a small current. As a result, the circuit for supplying the electron current E can be smaller, and higher integration and a lower cost of the semiconductor device 4a can be realized. The width of one fuse portion 33 can be reduced because two fuse portions 33 can be located in one opening 26. This configuration also can reduce the electron current E. Otherwise, the configuration, manufacturing method, operations, and effects according to the modification are similar to those of the fourth embodiment.

### Second Modification of Fourth Embodiment

The modification differs from the fourth embodiment in that a tilted portion is formed in the upper surface of the silicon film 30 at the vicinity of the region directly above the side surface of the opening 26.

FIG. 20 is a cross-sectional view showing a semiconductor device according to the modification.

In the semiconductor device 4b according to the modification as shown in FIG. 20, the tilted portion 30a is formed in the upper surface of the silicon film 30 at the vicinity of the region directly above the side surface of the opening 26.

According to the modification, the deposition and etching of silicon are perform simultaneously or alternately when forming the silicon film 30 in the process shown in FIG. 16C. As a result, the corners of the silicon film 30 are selectively etched. As a result, the tilted portion 30a is formed in the silicon film 30 at the vicinity of the region directly above the side surface of the opening 26 of the insulating film 20. The silicon film 30 is thinner in the region directly under the tilted portion 30a than at other portions.

According to the modification, the current concentrates in the region directly under the tilted portion 30a when the electron current E flows through the silicon film 30. Otherwise, the configuration, manufacturing method, operations, and effects according to the modification are similar to those of the fourth embodiment.

### Third Modification of Fourth Embodiment

The modification differs from the fourth embodiment in that the silicon film 30 includes a single-crystal portion and a polycrystalline portion.

### Configuration

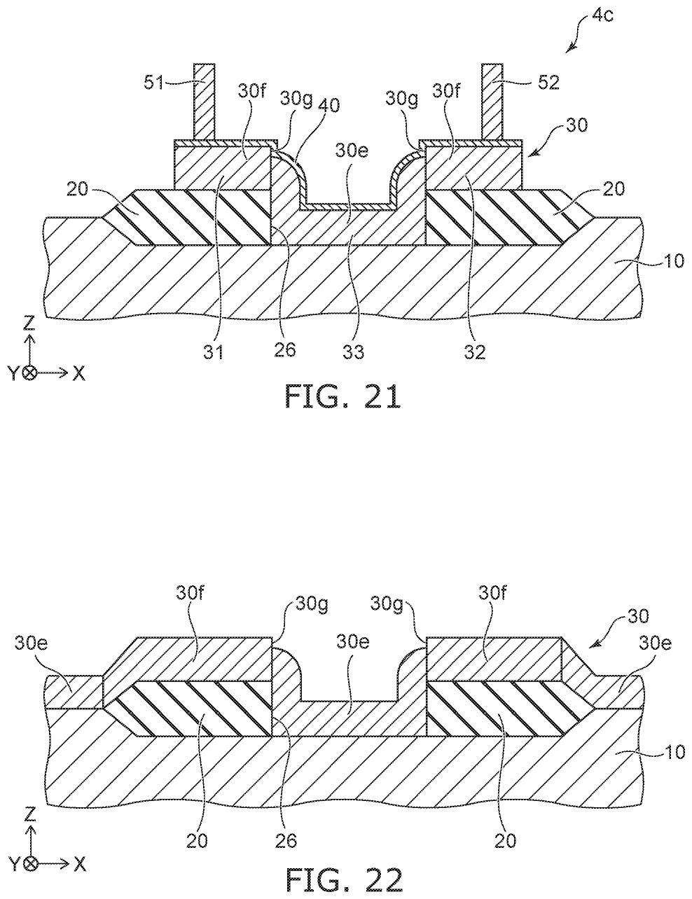

FIG. 21 is a cross-sectional view showing a semiconductor device according to the modification.

In the semiconductor device 4c according to the modification as shown in FIG. 21, the semiconductor substrate 10 is made of single-crystal silicon; and the insulating film 20 is made of silicon oxide. The portion of the silicon film 30 located on the semiconductor substrate 10 is a single-crystal portion 30e; and the portion of the silicon film 30 located on the insulating film 20 is a polycrystalline portion 30f. The pad portions 31 and 32 are substantially the polycrystalline portions 30f; and the fuse portion 33 is substantially the single-crystal portion 30e. A step 30g is formed at the single-crystal portion 30e and the boundary between the polycrystalline portion 30f. There are also cases where a step is not formed.

### Manufacturing Method

FIG. 22 is a process cross-sectional view showing a method for manufacturing the semiconductor device according to the modification.

First, the processes shown in FIGS. 16A and 16B are performed.

Then, the silicon film 30 is formed as shown in FIG. 22. At this time, the film formation conditions are such that a single-crystal silicon film is grown on the semiconductor substrate 10, which is made of single-crystal silicon. As a result, the single-crystal portion 30e is formed using the semiconductor substrate 10 as a starting point. The silicon film that is formed on the insulating film 20 becomes a polycrystal because silicon oxide is amorphous. Therefore, the polycrystalline portion 30f is formed on the insulating film 20. There are cases where the step 30g is formed at the boundary between the single-crystal portion 30e and the polycrystalline portion 30f due to the different growth rates of the two portions.

Then, the silicon film 30 is patterned as shown in FIG. 21. Then, the sidewall 60, the silicide layer 40, and the contacts 51 and 52 are formed. Thus, the semiconductor device 4c is formed.

### Effects

According to the modification, a step is formed in the silicon film 30 at the boundary between the single-crystal portion 30e and the polycrystalline portion 30f, and so the current concentrates easily at the portion of the silicide layer 40 covering the step. In the silicon film 30, the electrical resistivity of the single-crystal portion 30e is greater than the electrical resistivity of the polycrystalline portion 30f, and so the single-crystal portion 30e easily generates heat when the electron current E flows. Also, an electric field concentrates easily at the interface between the single-crystal portion 30e and the polycrystalline portion 30f. Electromigration is promoted thereby. Otherwise, the configuration, manufacturing method, operations, and effects according to the modification are similar to those of the fourth embodiment.

### Fifth Embodiment

The embodiment differs from the fourth embodiment in that the entire silicon film 30 is located in the opening 26 of the insulating film 20.

### Configuration

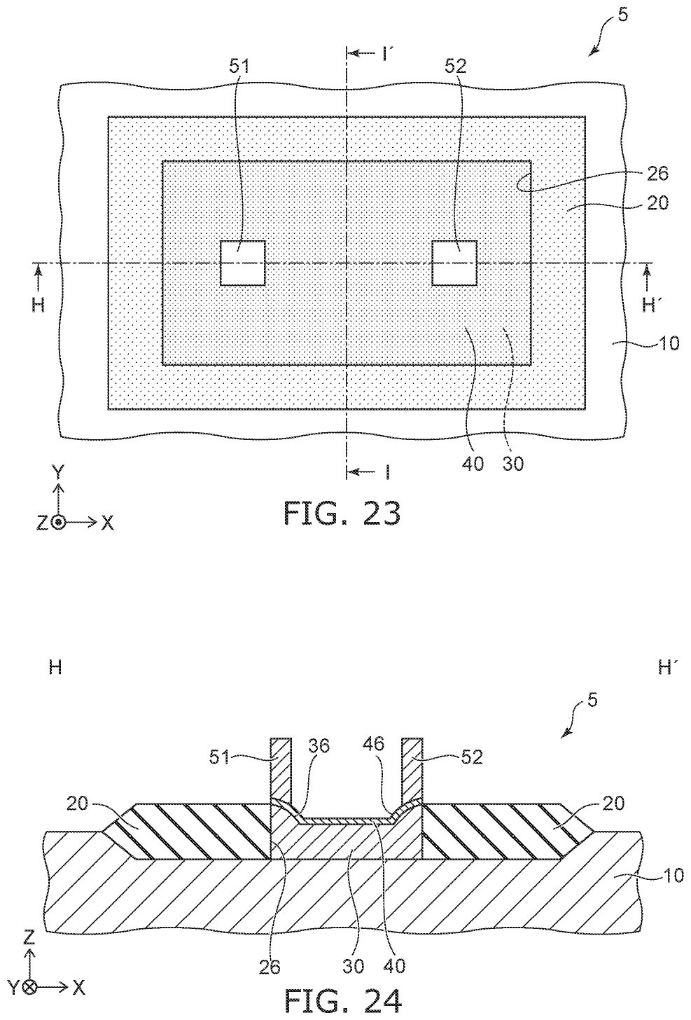

FIG. 23 is a plan view showing a semiconductor device according to the embodiment.

FIG. 24 is a cross-sectional view along line H-H′ shown in FIG. 23.

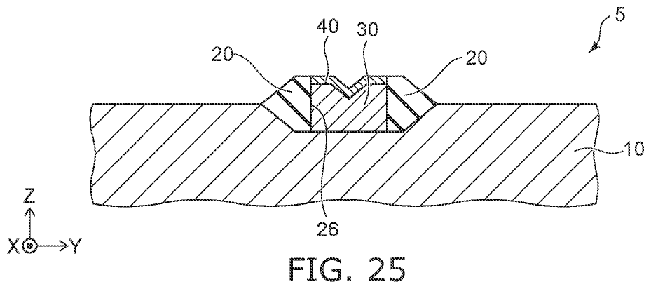

FIG. 25 is a cross-sectional view along line I-I′ shown in FIG. 23.

In the semiconductor device 5 according to the embodiment as shown in FIGS. 23 to 25, the silicon film 30 and the silicide layer 40 are located in the opening 26 of the insulating film 20. The recess 36 is formed in the upper surface of the silicon film 30. The recess 46 that reflects the recess 36 of the silicon film 30 is formed in the silicide layer 40. The contacts 51 and 52 are connected to portions of the silicide layer 40 so that the region directly above the recess 36 is interposed between the portions. For example, the side surfaces of the recess 46 of the silicide layer 40 are tilted with respect to the XY-plane; and the contacts 51 and 52 are connected to side surfaces of the recess 46 that face each other.

### Manufacturing Method

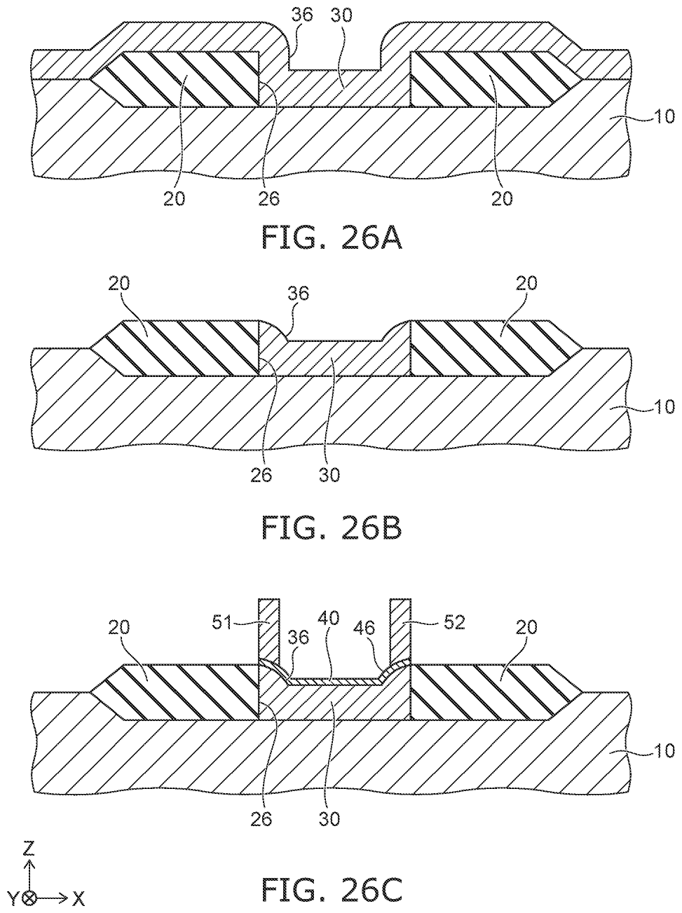

FIGS. 26A to 26C are process cross-sectional views showing a method for manufacturing the semiconductor device according to the embodiment.

First, the processes shown in FIGS. 16A to 16C are performed. As a result, the silicon film 30 that covers the semiconductor substrate 10 and the insulating film 20 is formed as shown in FIG. 26A. At this time, the recess 36 is formed in the upper surface of the silicon film 30 in the region directly above the opening 26 of the insulating film 20. The recess 36 is positioned inside the opening 26 when viewed from above.

Then, the silicon film 30 is etched as shown in FIG. 26B. The portion of the silicon film 30 located outside the opening 26 when viewed from above is removed thereby. As a result, the silicon film 30 in which the recess 36 is formed in the upper surface remains in the opening 26 of the insulating film 20.

Continuing as shown in FIG. 26C, the silicide layer 40 is formed at the upper surface of the silicon film 30. The silicide layer 40 also is formed only in the opening 26. The recess 46 that reflects the recess 36 of the silicon film 30 is formed in the upper surface of the silicide layer 40. Then, the contacts 51 and 52 are formed and connected to the side surfaces of the recess 46 of the silicide layer 40 that face each other. Thus, the semiconductor device 5 is manufactured.

### Operation

In the semiconductor device 5, when the electron current E flows through the silicide layer 40, the current concentrates and generates heat at the boundary portion between the bottom surface and side surface of the recess 46. Also, when the electron current E flows through the silicon film 30, the current concentrates and generates heat at the recess 36. As a result, electromigration can be promoted, and the fuse portion can be cut more effectively by a small current.

### Effects

According to the embodiment as well, similarly to the first embodiment, the electron current E concentrates at portions of the silicide layer and the silicon film that are not flat, and so electromigration can be promoted, and the fuse portion 33 can be cut by a small current. As a result, the circuit for supplying the electron current E can be smaller, and higher integration and a lower cost of the semiconductor device 5 can be realized. The electron current E also concentrates because the film thickness of the silicon film 30 is nonuniform in the Y-direction as well. Otherwise, the configuration, manufacturing method, operations, and effects according to the embodiment are similar to those of the fourth embodiment.

### Modification of Fifth Embodiment

The modification differs from the fifth embodiment in that two fuse portions 33 are formed in one opening 26 of the insulating film 20.

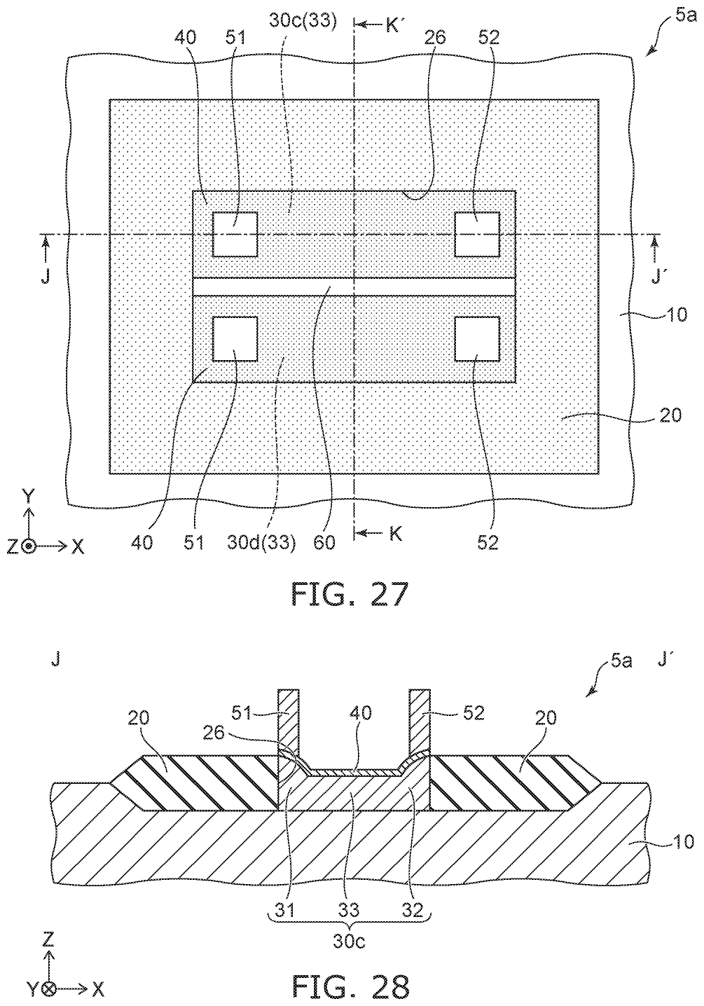

FIG. 27 is a plan view showing a semiconductor device according to the modification.

FIG. 28 is a cross-sectional view along line J-J′ shown in FIG. 27.

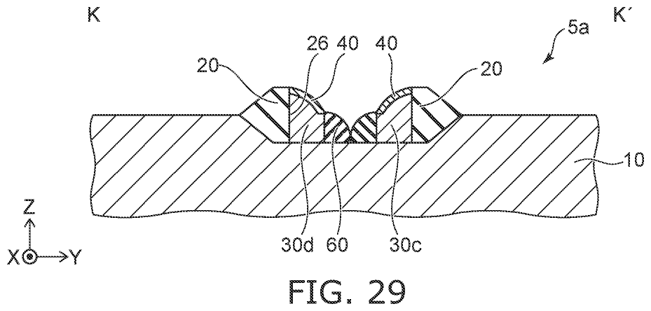

FIG. 29 is a cross-sectional view along line K-K′ shown in FIG. 27.

In the semiconductor device 5a according to the modification as shown in FIGS. 27 to 29, two silicon films 30c and 30d are located in one opening 26. The fuse portions 33 are formed respectively in the silicon films 30c and 30d. The sidewall 60 is located between the silicon film 30c and the silicon film 30d in the opening 26.

According to the modification, the width of one fuse portion 33 can be reduced because two fuse portions 33 can be located in one opening 26. As a result, the electron current E can be reduced, and the circuit for supplying the electron current E can be even smaller. As a result, even higher integration and a lower cost of the semiconductor device 5a can be realized. Otherwise, the configuration, manufacturing method, operations, and effects according to the modification are similar to those of the fifth embodiment.

### Other Embodiments

The positional relationship between the silicon film 30 and the opening 26 of the insulating film 20 is not limited to the embodiments and the modifications of the embodiments described above; and various forms are possible. Several specific examples will now be described.

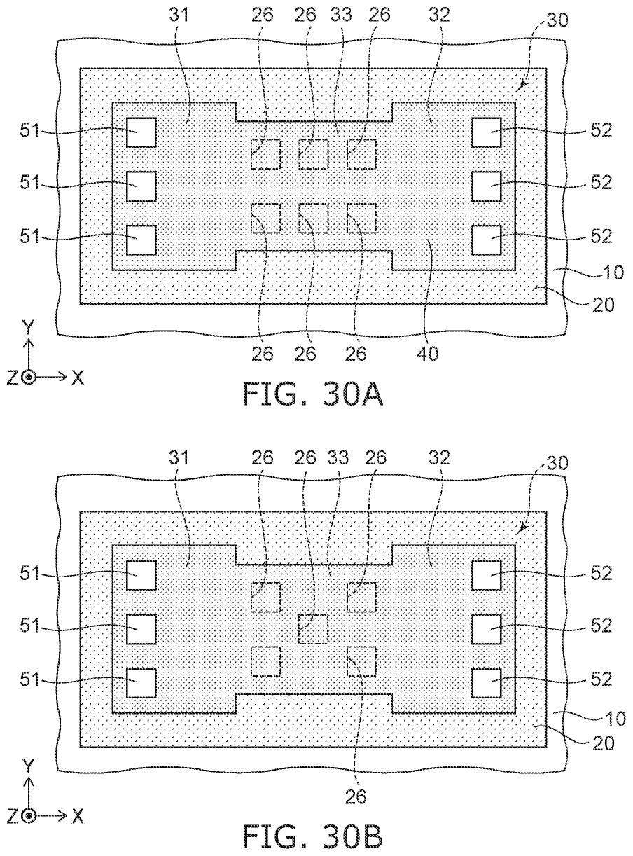

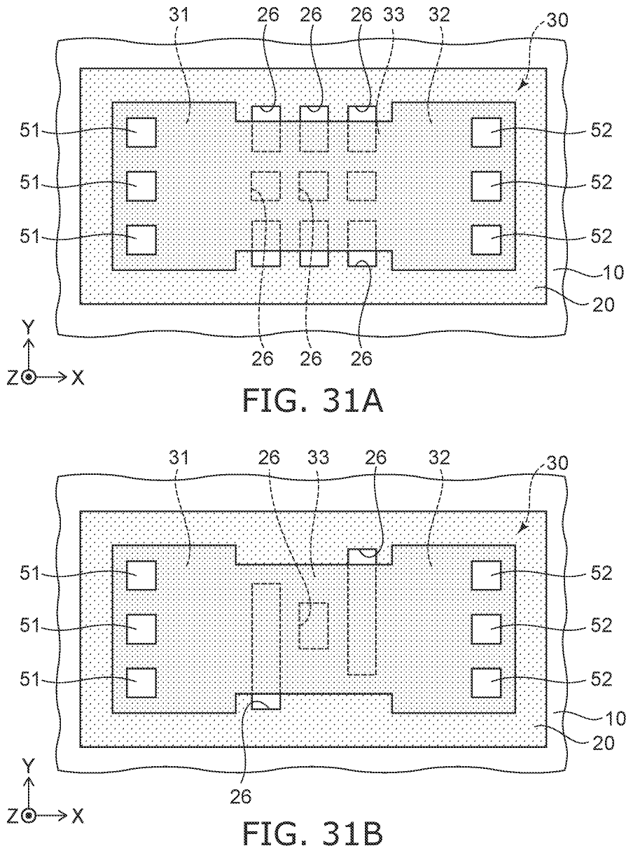

FIGS. 30A to 31B are plan views showing other embodiments.

For example, as shown in FIG. 30A, multiple openings 26 of the same size may be arranged in a matrix configuration; and the silicon film 30 may be arranged to cover all of the multiple openings 26.

As shown in FIG. 30B, multiple openings 26 of the same size may be arranged in a staggered configuration; and the silicon film 30 may be arranged to cover all of the multiple openings 26.

As shown in FIG. 31A, multiple openings 26 of mutually-different sizes may be arranged in a matrix configuration; and the silicon film 30 may be arranged to cover a portion of the multiple openings 26.

As shown in FIG. 31B, multiple openings 26 of mutually-different sizes may be arranged arbitrarily; and the silicon film 30 may be arranged to cover a portion of the multiple openings 26.

Thus, one or multiple openings 26 may be provided. The silicon film 30 may cover the entire opening 26 or a portion of the opening 26. The shape of the opening 26 is not limited to a rectangle and may be, for example, a circle, a rectangle with rounded corners, a trench shape extending in a direction tilted with respect to the X-direction and Y-direction, or a lattice shape.

According to the embodiments and the modifications of the embodiments described above, portions at which the electron current E concentrates are formed in the silicide layer 40 and the silicon film 30 by making the shape of the upper surface of the insulating film 20 nonuniform so that the shape of the silicon film 30 formed on the upper surface of the insulating film 20 is nonuniform. However, portions at which the current concentrates may be formed by forming the silicon film 30 on a flat region of the upper surface of the insulating film 20 and by patterning the silicon film 30 by etching, etc. Portions at which the current concentrates also may be formed by patterning the silicide layer 40 by etching, etc.

Although examples are shown in the embodiments and the modifications of the embodiments described above in which the fuse portion is included in an OTPROM, applications are not limited thereto; the fuse portion may be used to disconnect a defective portion or select a redundant circuit.

According to the embodiments described above, a semiconductor device and a method for manufacturing a semiconductor device that include a fuse that is electrically disconnectable by a small current can be realized.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions. Additionally, the embodiments described above can be combined mutually.

What is claimed is:

1. A semiconductor device, comprising:
a semiconductor substrate;
an insulating film located on the semiconductor substrate, a first recess being formed in an upper surface of the insulating film;
a silicon film located on the insulating film, the silicon film including an impurity, a second recess being formed in an upper surface of the silicon film in a region directly above the first recess;
a silicide layer located on the silicon film, the silicide layer contacting the silicon film; and
a first contact and a second contact connected to portions of the silicide layer, a region directly above the second recess being interposed between the portions.

2. The device according to claim 1, wherein
the insulating film includes:
a first LOCOS film; and
a second LOCOS film,
the first LOCOS film and the second LOCOS film are connected to each other, and
the first recess is at a connection portion between the first LOCOS film and the second LOCOS film.

3. A semiconductor device, comprising:
a semiconductor substrate;
an insulating film located on the semiconductor substrate, an opening being formed in the insulating film;
a silicon film located on the insulating film to straddle the opening, the silicon film including an impurity;
a silicide layer located on the silicon film, the silicide layer contacting the silicon film; and
a first contact and a second contact connected to portions of the silicide layer, a region directly above the opening being interposed between the portions.

4. A semiconductor device, comprising:
a semiconductor substrate;
an insulating film located on the semiconductor substrate, an opening being formed in the insulating film;
a silicon film located on the insulating film to cover the opening, the silicon film including an impurity;
a silicide layer located on the silicon film, the silicide layer contacting the silicon film; and
a first contact and a second contact connected to portions of the silicide layer, a region directly above the opening being interposed between the portions.

5. A semiconductor device, comprising:
a semiconductor substrate;
an insulating film located on the semiconductor substrate, an opening being formed in the insulating film;
a silicon film located in the opening, the silicon film including an impurity, a recess being formed in an upper surface of the silicon film;
a silicide layer located on the silicon film, the silicide layer contacting the silicon film; and
a first contact and a second contact connected to portions of the silicide layer, a region directly above a bottom surface of the recess being interposed between the portions.

6. A method for manufacturing a semiconductor device, the method comprising:
forming a first LOCOS film and a second LOCOS film at an upper surface of a semiconductor substrate so that the first LOCOS film and the second LOCOS film are connected to each other;
forming a silicon film on a region including a connection portion between the first LOCOS film and the second LOCOS film, the silicon film including an impurity;
forming a silicide layer at an upper surface of the silicon film; and
connecting a first contact and a second contact to regions of the silicide layer, a region directly above the connection portion being interposed between the regions of the silicide layer.

7. A method for manufacturing a semiconductor device, the method comprising:
forming an insulating film at an upper surface of a semiconductor substrate;
forming an opening in the insulating film;
forming a silicon film at a region including a region directly above the opening, the silicon film including an impurity;
forming a silicide layer at an upper surface of the silicon film; and
connecting a first contact and a second contact to regions of the silicide layer, a region directly above the opening being interposed between the regions of the silicide layer.

8. The method according to claim 7, wherein
the silicon film is formed to straddle the opening.

9. The method according to claim 7, wherein
the silicon film is formed to cover the opening.

10. A method for manufacturing a semiconductor device, the method comprising:
forming an insulating film at an upper surface of a semiconductor substrate;
forming an opening in the insulating film;
forming a silicon film in the opening, the silicon film including an impurity, a recess being formed in an upper surface of the silicon film;
forming a silicide layer at an upper surface of the silicon film; and
connecting a first contact and a second contact to portions of the silicide layer, a region directly above a bottom surface of the recess being interposed between the portions.

11. The method according to claim 10, wherein
the forming of the silicon film includes:
forming a silicon film on the insulating film to cover the opening; and
removing a portion of the silicon film located outside the opening when viewed from above.
